(19) United States
(12) Patent Application Publication
(10) Pub. No.: US 2011/0001180 A1
(43) Pub. Date: Jan. 6, 2011

(54) NONVOLATILE SEMICONDUCTOR MEMORY DEVICE

(76) Inventors: Kazunori MASUDA, Yokohama-shi (JP); Mutsuo Morikado, Yokohama-shi (JP); Kiyomi Naruke, Sagamihara-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/768,086

(22) Filed: Apr. 27, 2010

(30) Foreign Application Priority Data
Jul. 6, 2009 (JP) 2009-159975

(51) Int. Cl. H01L 27/115; H01L 21/8247

(52) U.S. Cl. 257/321; 438/594; 438/257; 257/E21.68; 257/E27.103

(57) ABSTRACT

In a nonvolatile semiconductor memory device having a plurality of nonvolatile memory cells integrated on a semiconductor substrate, each of the memory cells includes a tunnel insulating film formed on the semiconductor substrate, a floating gate electrode formed on the tunnel insulating film, a first interelectrode insulating film formed on the upper surface of the floating gate electrode, a second interelectrode insulating film formed to cover the side surfaces of the floating gate electrode and the first interelectrode insulating film, and a control gate electrode formed on the second interelectrode insulating film.

### CROSS-REFERENCE TO RELATED APPLICATIONS

This application is based upon and claims the benefit of priority from prior Japanese Patent Application No. 2009-159975, filed Jul. 6, 2009, the entire contents of which are incorporated herein by reference.

### BACKGROUND OF THE INVENTION

1. Field of the Invention

This invention relates to a nonvolatile semiconductor memory device and more particularly to a nonvolatile semiconductor memory device comprising stacked gate nonvolatile memory cells each of which comprises a floating gate electrode and control gate electrode.

2. Description of the Related Art

In a nonvolatile semiconductor memory device, for example, in a NAND flash memory, memory cells are further miniaturized in order to increase the memory capacity. However, the further memory cells are miniaturized, the more significant the deterioration in element characteristics becomes, which has a large influence on memory cells and flash memories.

In a normal stacked gate flash memory, a gate insulating film (interelectrode insulating film) between the control gate electrode and the floating gate electrode is formed along the side surfaces and upper surface of the floating gate electrode. Further, the upper edge portion of the floating gate electrode is rounded in a process for processing the floating gate electrode, and the shape of the upper end portion is configured by a flat portion near the central portion and curved surface portions of both end portions.

Therefore, an electric field applied to the interelectrode insulating film is locally increased in the curved surface portions in comparison with the flat portion in the upper end portion of the floating gate electrode at the high-voltage application time when a memory cell write/erase operation is performed. As a result, a leak current occurring in the interelectrode insulating film is increased. An increase in the leak current means that charges move from the floating gate electrode to the control gate electrode at the high-voltage application time when the memory cell write/erase operation is performed, and this degrades the charge injection characteristic of the flash memory cell. If the film thickness of the interelectrode insulating film is increased to prevent the above degradation, the ratio of the capacitive coupling between the control gate electrode and the floating gate electrode of the memory cell will be degraded. An increase in the electric field applied to the interelectrode insulating film on the upper end portion of the floating gate electrode leads to a factor that limits the film thickness of the interelectrode insulating film and degrades the performance of the memory cell.

Further, if the memory cells are miniaturized, the area of the curved surface portion in the shape of the upper end portion of the floating gate electrode is increased and the electric field applied to the interelectrode insulating film is further increased. Therefore, the leak current occurring in the interelectrode insulating film increases with miniaturization of the memory cells.

There is proposed a method for forming an interelectrode insulating film to have a large film thickness in an upper edge portion of a floating gate electrode in a word line direction in order to reduce the leak current occurring in the interelectrode insulating film (for example, see JP-A 2008-300427 (KOKAI)). However, with this method, a process for sufficiently rounding the upper edge portion of the floating gate electrode and forming the interelectrode insulating film thick only on the upper edge portion is required. It is extremely difficult to produce the above shape since the manufacturing process would be highly complex.

### BRIEF SUMMARY OF THE INVENTION

According to one aspect of this invention, there is provided a nonvolatile semiconductor memory device comprising:

a plurality of nonvolatile memory cells formed on a semiconductor substrate, each of the memory cells including:

a tunnel insulating film formed on the semiconductor substrate, a floating gate electrode formed on the tunnel insulating film, an interelectrode insulating film formed to cover an upper surface and a part of side surfaces of the floating gate electrode, a film thickness of the interelectrode insulating film being made larger on the upper surface of the floating gate electrode than on the side surface of the floating gate electrode, and a control gate electrode formed on the interelectrode insulating film.

According to another aspect of this invention, there is provided a manufacturing method of a nonvolatile semiconductor memory device having a plurality of nonvolatile memory cells integrated on a semiconductor substrate, comprising:

forming a floating gate electrode on the semiconductor substrate with a tunnel insulating film disposed therebetween, forming a first interelectrode insulating film on the floating gate electrode, processing the first interelectrode insulating film and floating gate electrode into a gate pattern, forming a second interelectrode insulating film to cover the first interelectrode insulating films and a part of side surfaces of the floating gate electrodes processed into the gate pattern, and forming a control gate electrode on the second interelectrode insulating film.

According to another aspect of this invention, there is provided a manufacturing method of a nonvolatile semiconductor memory device having a plurality of nonvolatile memory cells integrated on a semiconductor substrate, comprising:

forming a tunnel insulating film on the substrate, forming a floating gate electrode on the tunnel insulating film, forming a first interelectrode insulating film on the floating gate electrode, processing the first interelectrode insulating film and floating gate electrode into a stripe pattern in a gate length direction, forming a second interelectrode insulating film to cover the first interelectrode insulating films and a part of side surfaces of the floating gate electrodes processed into the stripe pattern, forming a control gate electrode on the second interelectrode insulating film, and processing the control gate electrode, second interelectrode insulating film, first interelectrode insulating film and floating gate electrode into a stripe pattern in a gate width direction.

### BRIEF DESCRIPTION OF THE DRAWING

FIG. 1 is a plan view showing the schematic structure of a flash memory cell array according one embodiment of this invention.

FIG. 2 is a cross-sectional view taken along the line A-A′ of FIG. 1.

FIG. 3 is a cross-sectional view taken along the line B-B′ of FIG. 1.

FIGS. 4A, 4B are cross-sectional views showing the relation between the upper end portion of the floating gate electrode and the interelectrode insulating film in the case of a comparison example.

FIGS. 5A, 5B are cross-sectional views showing the relation between the upper end portion of the floating gate electrode and the interelectrode insulating film in the case of this embodiment.

FIGS. 6A to 6G are cross-sectional views showing manufacturing steps of a flash memory according to the embodiment.

### DETAILED DESCRIPTION OF THE INVENTION

This invention will be explained in detail with reference to an embodiment of this invention shown in the accompanying drawings.

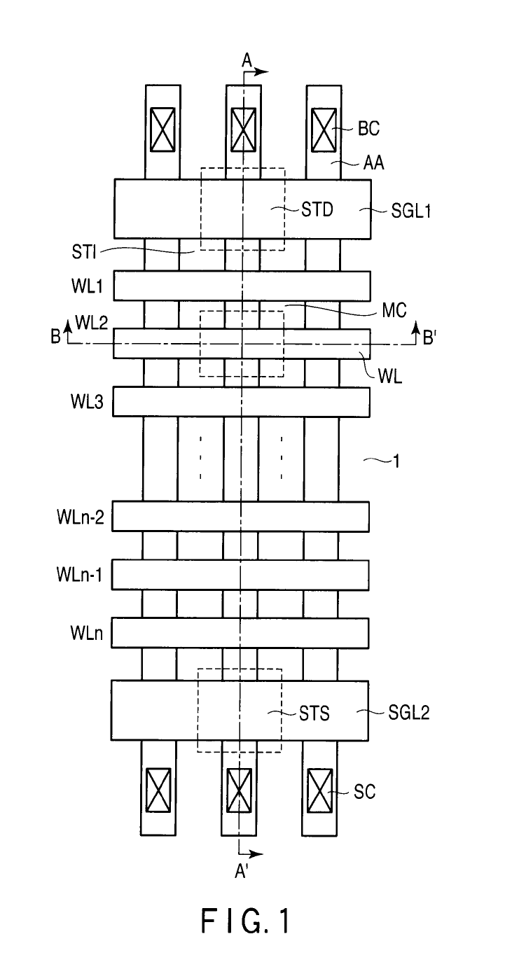

The structure of a nonvolatile semiconductor memory device according to one embodiment of this invention is explained with reference to FIGS. 1 to 3. In this embodiment, an example in which a NAND flash memory is used as the nonvolatile semiconductor memory device is explained.

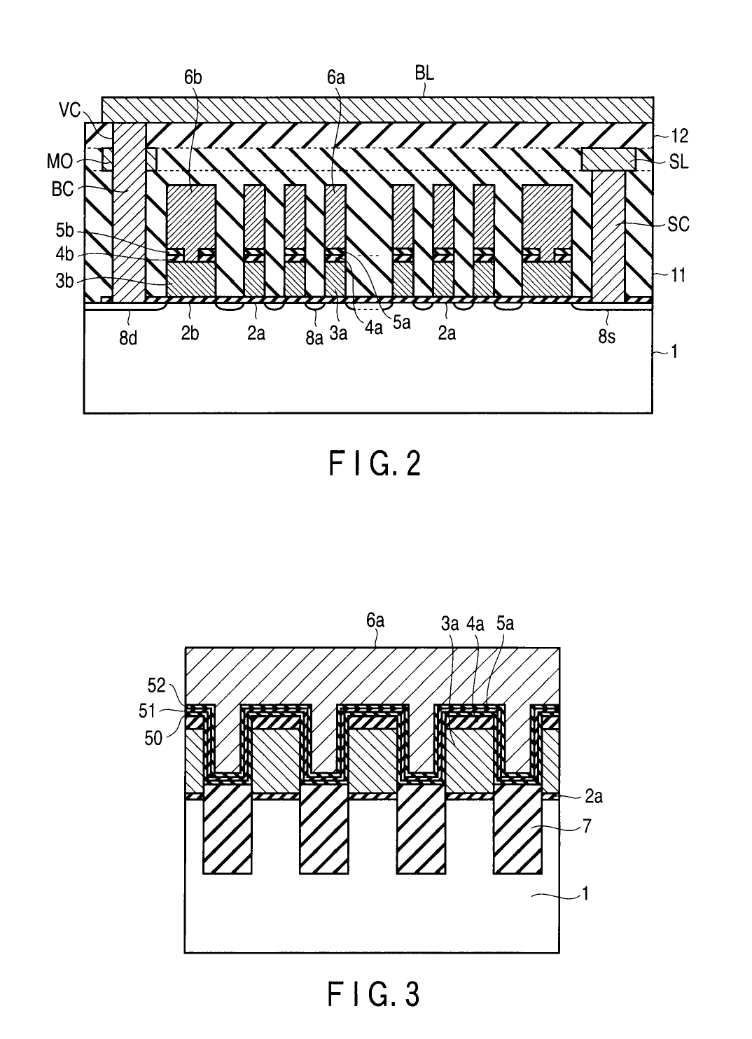

FIG. 1 is a plan view showing the schematic structure of a memory cell array of a flash memory according this embodiment, FIG. 2 is a cross-sectional view taken along the line A-A′ of FIG. 1 and FIG. 3 is a cross-sectional view taken along the line B-B′ of FIG. 1. FIG. 2 corresponds to the cross section in the channel length direction (gate length direction) of a memory cell MC and FIG. 3 corresponds to the cross section in the channel width direction (gate width direction) of the memory cell MC.

As shown in FIG. 1, in the memory cell array of the flash memory, the surface area of a semiconductor substrate 1 is configured by element areas (active areas) AA each sandwiched between element isolation areas STI (Shallow Trench Isolation). On the element areas AA, a plurality of memory cells MC and selection transistors STD, STS are formed.

The memory cells MC are arranged on the element areas AA and a plurality of memory cells MC are serially connected. The plural memory cells that are serially connected are hereinafter referred to as a memory cell string. The selection transistors STD, STS are arranged on both end portions of the memory cell string. The configuration comprising the memory cell string and selection transistors STD, STS is hereinafter referred to as a NAND cell unit.

A plurality of NAND cell units are arranged side by side in the word line direction and the respective memory cells MC of the respective NAND cell units are connected to word lines WL (WL1 to WLn) that intersect with the element areas AA. In this case, the memory cells MC arranged on the same line are connected to the common word line WL. Further, the selection transistors STD, STS are respectively connected to selection gate lines SGL1, SGL2.

One end of each NAND cell unit is connected to a corresponding one of bit lines (not shown) arranged in the same direction as the element areas AA via a bit line contact BC. Further, the other end of each NAND cell unit is connected to a corresponding one of source lines (not shown) arranged in the same direction as the word lines via a source line contact SC.

As shown in FIGS. 2 and 3, the memory cell MC used in this embodiment is a MIS (Metal-Insulator-Semiconductor) transistor with a stacked gate structure in which a control gate electrode 6a is laminated on a floating gate electrode 3a.

In the semiconductor substrate 1, a well region (not shown) is formed and the NAND cell units are formed on the well region. That is, the memory cells MC each configured by a gate insulating film 2a, floating gate electrode 3a, interelectrode insulating films 4a, 5a and control gate electrode 6a and the selection transistors STD, STS each configured by a gate insulating film 2b, lower electrode 3b, interelectrode insulating films 4b, 5b and upper electrode 6b are provided on the substrate 1.

The gate insulating film 2a is provided on the surface of the semiconductor substrate 1. In the memory cell MC, the gate insulating film 2a functions as a tunnel insulating film. The gate insulating film 2a of the memory cell MC is hereinafter referred to as a tunnel insulating film.

The floating gate electrode 3a is provided on the gate insulating film 2a formed on the surface of the semiconductor substrate 1. The floating gate electrode 3a functions as a charge storage layer used to hold data written into the memory cell MC and is formed of a polysilicon film, for example.

The floating gate electrodes 3a in the plural memory cells MC formed on the element areas AA adjacent in the channel width direction are electrically isolated by element isolation insulating films 7 formed in the element isolation areas STI and buried in the semiconductor substrate 1. In this case, the upper end of the element isolation insulating film 7 recedes from the upper end of the floating gate electrode 3a towards the semiconductor substrate 1 side. That is, the element isolation insulating film 7 is buried and formed higher than the lowermost surface of the floating gate electrodes 3a and lower than the uppermost surface thereof.

On the upper surfaces of the floating gate electrodes 3a, the first interelectrode insulating films 4a are disposed. Further, the second interelectrode insulating film 5a is disposed on the element isolation insulating films 7 to surround the first interelectrode insulating films 4a and floating gate electrodes 3a. The floating gate electrode 3a and control gate electrode 6a are electrically isolated due to the presence of the interelectrode insulating films 4a, 5a.

For example, one of a silicon oxide film, silicon nitride film and aluminum oxide film is used to form the interelectrode insulating film 4a. A material used for forming the interelectrode insulating film 4a is not limited to the above films and another insulating material may be used. The film thickness of the interelectrode insulating film 4a is approximately 6 to 15 nm, for example.

Further, for example, the interelectrode insulating film 5a has a laminated structure containing a plurality of insulating films 50, 51, 52. In the example shown in FIGS. 2 and 3, the structure of the interelectrode insulating film 5a is attained as a structure having the insulating film 51 sandwiched between the two insulating films 50 and 52. The film thickness T2 of the interelectrode insulating film 5a of the laminated structure is approximately 8 nm to 20 nm, for example.

As the insulating film 51, a ferroelectric film of silicon nitride (SiN), aluminum oxide (Al₂O₃), hafnium oxide (HfO₂), tantalum oxide (Ta₂O₅), lanthanum oxide (La₂O₃), LaLiO₃, zirconium oxide (ZrO₂) or yttrium oxide (Y₂O₃) is used. In this case, silicon or nitrogen may be further added to the ferroelectric film formed of the above oxide film.

For example, each of the insulating films 50, 52 is an insulating film having a dielectric constant smaller than that of the insulating film 51, for which a silicon oxide film is mainly used. When the insulating film 51 is formed of a ferroelectric film, a silicon nitride film may be used.

In this embodiment, the interelectrode insulating film 5a has a three-layered structure, but this embodiment is not limited to this case and can of course be applied to a multi-layered structure obtained by laminating four or more insulating films. Further, the interelectrode insulating film 5a may be a single-layered film formed of a ferroelectric film.

The control gate electrode 6a is formed on the interelectrode insulating film 5a. That is, the control gate electrode 6a is formed to cover the interelectrode insulating film 5a and, as a result, the control gate electrode 6a covers the side surfaces of the floating gate electrode 3a with the interelectrode insulating films 4a, 5a disposed therebetween.

As the control gate electrode 6a, for example, a silicide film is used to reduce the electrical resistance. However, this is not limitative and the control gate electrode 6a may be formed of a single-layered structure of a polysilicon film or a two-layered structure (polycide structure) comprising a polysilicon film and a silicide film laminated on the polysilicon film.

As the silicide film, for example, a tungsten silicide film (WSi₂), molybdenum silicide film (MoSi₂), cobalt silicide film (CoSi₂), titanium silicide film (TiSi₂) and nickel silicide film (NiSi₂) may be used.

The control gate electrode 6a functions as the word line WL and are commonly used by adjacent memory cells. Therefore, the control gate electrode 6a is formed not only above the floating gate electrode 3a but also above the element isolation insulating film 7.

Diffusion regions 8a are formed in the semiconductor substrate 1 and the diffusion regions 8a function as source/drain regions of the memory cells MC. In the following description, the diffusion region 8a is referred to as a source/drain region. The source/drain regions 8a are formed on one element area AA and each source/drain region is commonly used by adjacent memory cells MC. Thus, the plural memory cells MC are serially connected to form one memory cell string.

The selection transistors STD, STS are arranged on one end and the other end of the series-connected plural memory cells MC (memory cell string).

The selection transistors STD, STS are formed at the time and in the same process as those of formation of the memory cells MC. Therefore, in the gate structures of the selection transistors STD, STS, the upper gate electrode 6b is laminated above the lower gate electrode 3b with the interelectrode insulating films 4b, 5b disposed therebetween, as in the case of the memory cell MC. The lower gate electrode 3b has the same structure as that of the floating gate electrode 3a and the upper gate electrode 6b has the same structure as that of the control gate electrode 6a.

However, in the selection transistors STD, STS, the interelectrode insulating films 4b, 5b have opening portions Q formed therein and the upper gate electrode 6b is electrically connected to the lower gate electrode 3b on the gate insulating film 2b via the opening portion Q.

One of the diffusion regions 8a is formed in the side portion of the selection transistor STD on the cell side and a diffusion region 8d is formed in the side portion thereof on the opposite side. Another diffusion region 8a is formed in the side portion of the selection transistor STS on the cell side and a diffusion region 8s is formed in the side portion thereof on the opposite side.

The diffusion regions 8a, 8d, 8s function as the source/drain regions of the selection transistors STD, STS. The selection transistors STD, STS commonly utilize the diffusion regions 8a with the adjacent memory cells MC. Thus, the plural memory cells MC and selection transistors STD, STS are serially connected on one element area AA to configure one NAND cell unit.

In the selection transistor STD formed on the drain side of the NAND cell unit, the drain diffusion layer 8d of the selection transistor STD is connected to a bit line contact portion BC buried in an inter-level insulating layer 11. The bit line contact BC is connected to the bit line BL via a metal interconnection MO and via contact VC formed in an inter-level insulating layer 12.

In the selection transistor STS formed on the source side of the NAND cell unit, the source diffusion layer 8s of the selection transistor is connected to a source line SL via a source line contact SC buried in the inter-level insulating layer 11.

As shown in FIG. 3, the flash memory of this embodiment has the interelectrode insulating films 5a formed on the side surfaces of the floating gate electrodes 3a and the interelectrode insulating films 4a, 5a formed on the upper surfaces thereof. This embodiment has a feature that the film thickness of the interelectrode insulating films 4a, 5a formed on the upper surfaces of the floating gate electrodes 3a is larger than that of the interelectrode insulating films 5a formed on the side surfaces of the floating gate electrodes 3a. By increasing the film thickness of the interelectrode insulating films 4a, 5a formed on the upper surface of the floating gate electrode 3a, the intensity of an electric field applied between the upper portion of the floating gate electrode 3a and the control gate electrode 6a can be alleviated and reduced in comparison with a case wherein the interelectrode insulating film 5a is formed in direct contact with the upper surface of the floating gate electrode 3a.

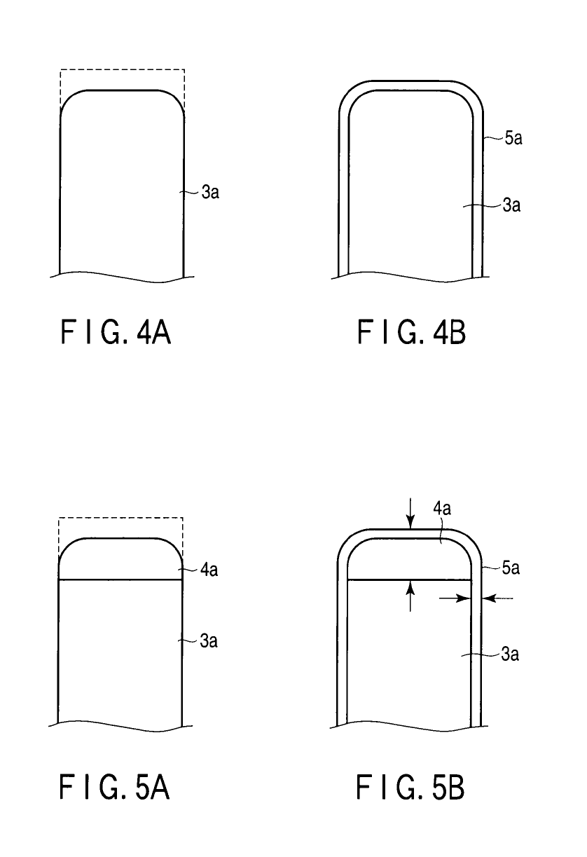

With the structure of this embodiment, the reason why the intensity of an electric field applied between the upper portion of the floating gate electrode 3a and the control gate electrode 6a can be alleviated and reduced is explained with reference to FIGS. 4A, 4B and FIGS. 5A, 5B.

In the case of the structure of a comparison example in which the first interelectrode insulating films 4a are not formed, the upper end portion of the floating gate electrode 3a may be etched by a small amount according to the etching characteristic by an etching process performed when the element isolation insulating film 7 recedes from the upper end of the floating gate electrode 3a towards the semiconductor substrate 1 side. As a result, as shown in FIG. 4A, the upper end portion of the floating gate electrode 3a recedes and the shape of the right and left end portions of the upper end portion obtained after etching will be rounded. Then, if the interelectrode insulating film 5a is formed, the shape as shown in FIG. 4B is obtained. Therefore, an electric field that is higher in the curved portions than in the flat portion is applied to the interelectrode insulating film 5a on the upper end surface of the floating gate electrode 3a when a high voltage is applied at the data write/erase time. As a result, a leak current will be increased.

On the other hand, in this embodiment, as shown in FIG. 5A, the first interelectrode insulating film 4a is formed on the upper surface of the floating gate electrode 3a. Therefore, the upper surface of the floating gate electrode 3a will not be exposed to an etching atmosphere in an etching process performed when the element isolation insulating film 7 recedes from the upper end of the floating gate electrode 3a towards the semiconductor substrate 1 side. As a result, the shape of the upper end portion of the floating gate electrode 3a can be protected. Then, if the second interelectrode insulating film 5a is formed, as shown in FIG. 5B, the total film thickness of the interelectrode insulating films 4a, 5a on the upper surface of the floating gate electrode 3a becomes larger than the film thickness of the interelectrode insulating film 5a on the side surface thereof. Therefore, it becomes possible to prevent an electric field higher than an electric field applied to the side surface of the floating gate electrode 3a from being applied to the interelectrode insulating film 5a on both end portions of the upper end surface of the floating gate electrode 3a. As a result, a leak current occurring in the interelectrode insulating film 5a between the control gate electrode 6a and the floating gate electrode 3a can be reduced.

In this embodiment, the coupling capacity occurring between the upper portion of the floating gate electrode 3a and the control gate electrode 6a facing the upper portion thereof becomes much smaller than the coupling capacity occurring between the side portion of the floating gate electrode 3a and the control gate electrode 6a facing the side portion thereof. However, the coupling capacity used for injecting charges into the floating gate electrode 3a acting as a charge storage layer or extracting charges from the floating gate electrode 3a can be sufficiently attained by the capacity present between the side portion of the floating gate electrode 3a and the control gate electrode 6a facing the side portion thereof.

In order to attain a sufficiently large coupling capacity of the memory cell, it is preferable to use a floating gate electrode 3a with large film thickness and increase the facing area between the side surfaces of the floating gate electrode 3a and the control gate electrode 6a.

Thus, the memory cell MC of the flash memory in this embodiment performs the data write/erase operation by mainly using the coupling capacity associated with the side portions of the floating gate electrode 3a. Therefore, an electric field can be suppressed from being concentrated on the upper portion of the floating gate electrode 3a by forming the interelectrode insulating film 4a between the control gate electrode 6a and the upper portion of the floating gate electrode 3a in a case where the radius of curvature of the upper portion of the floating gate electrode 3a is made small by miniaturization of the memory cells.

As a result, the intensity of the electric field applied between the upper portion of the floating gate electrode 3a and the control gate electrode 6a can be reduced. Therefore, in this embodiment, the leak-resistant property of the memory cell can be prevented from being degraded by miniaturization of the memory cell.

Further, in the memory cell of this embodiment, the upper portion of the floating gate electrode 3a contributes only slightly to the coupling capacity of the memory cell. Therefore, it becomes possible to reduce a variation in the coupling capacities of the memory cells provided in the memory cell array due to a variation in the shape of the upper portion of the floating gate electrode 3a. Thus, in this embodiment, a variation of the element characteristics of the memory cell such as the write potential and erase potential of the memory cell can be suppressed.

According to this embodiment, the film thickness of the interelectrode insulating film between the control gate electrode 6a and the floating gate electrode 3a is made larger in the upper portion of the floating gate electrode 3a than in another area. As a result, a phenomenon by which a highly intense electric field is applied to the interelectrode insulating film due to the shape of the upper end portion of the floating gate electrode 3a to increase a leak current can be previously prevented. Therefore, it is possible to attain a characteristic such that electrons are injected into the floating gate electrode 3a when a high voltage is applied at the data write/erase operation time of the memory cell.

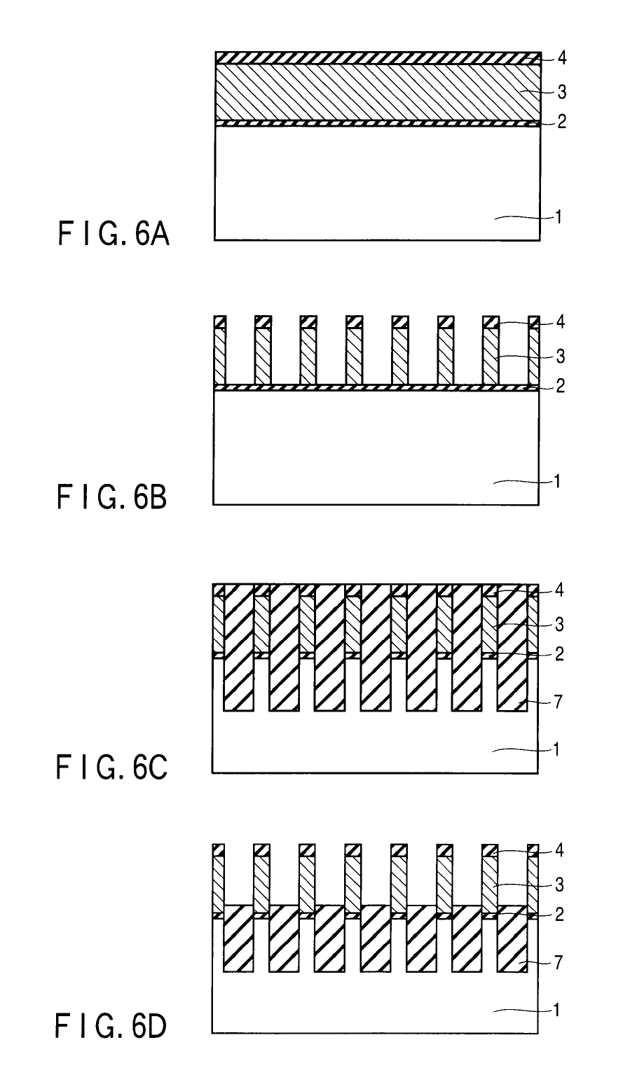

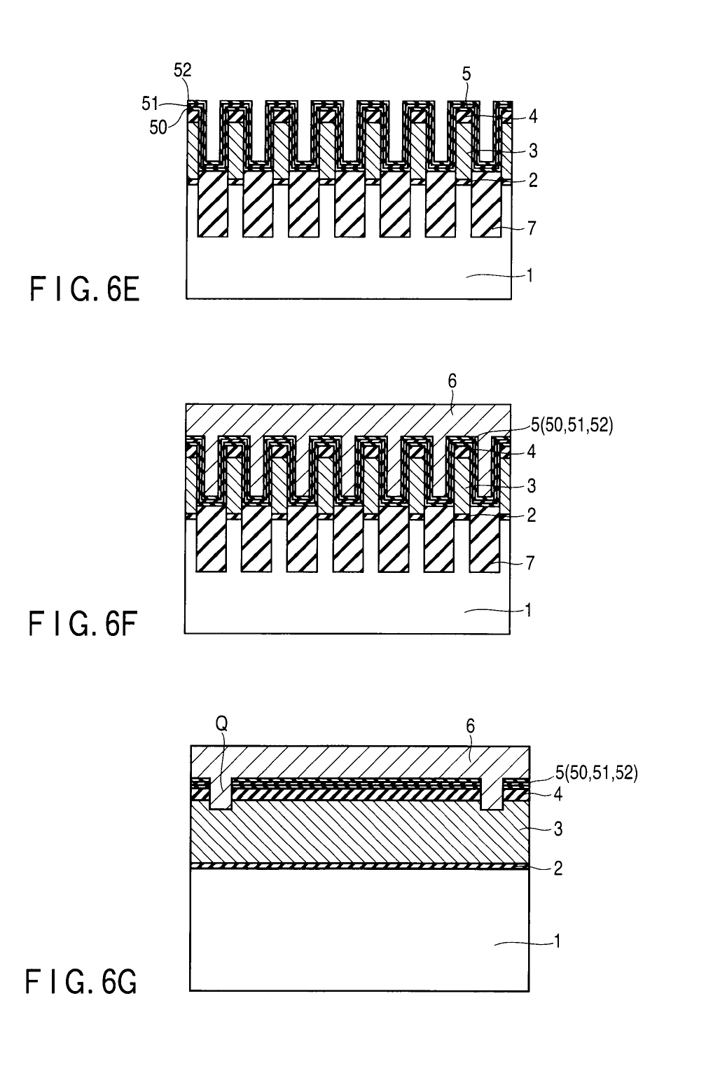

Next, one example of a manufacturing method of the NAND flash memory shown in FIGS. 1 to 3 is explained with reference to FIGS. 6A to 6G. FIGS. 6A to 6F correspond to the cross section of FIG. 3 and FIG. 6G corresponds to the cross section of FIG. 2.

First, as shown in FIG. 6A, an insulating film 2 used as tunnel insulating films of memory cells is formed on the surface of a semiconductor substrate 1 by a thermal oxidation method, for example. The insulating film 2 is also used as gate insulating films of selection transistors. Then, a first conductive layer 3 used as floating gate electrodes of the memory cells and lower electrodes of the selection transistors is formed on the insulating film 2 by use of a CVD (Chemical Vapor Deposition) method, for example. After this, an insulating film 4 used as first interelectrode insulating films is deposited on the conductive layer 3 by use of the CVD method, for example.

The conductive layer 3 is a polysilicon film, for example. Further, as the insulating film 4, one of a silicon oxide film, silicon nitride film and aluminum oxide film is used, for example. A material used for forming the insulating film 4 is not limited to the above materials and another insulating material may be used.

Next, as shown in FIG. 6B, the insulating film 4 is processed into a stripe pattern along the channel length direction (gate length direction) by selectively etching the insulating film 4 by use of a lithography technique and RIE (Reactive Ion Etching) method. Then, the conductive layer 3 is selectively etched by use of, for example, the RIE method with the thus processed insulating film 4 used as a mask.

Subsequently, as shown in FIG. 6C, for example, the insulating film 2 and semiconductor substrate 1 are sequentially etched by use of the RIE method to form grooves of STI portions in the semiconductor substrate 1. Then, insulating films 7 used as element isolation insulating films are buried and formed in the grooves. The films 7 are formed by making the films flush with the upper surfaces of the insulating films 4 by use of a CMP (Chemical Mechanical Polishing) method after formation of the films.

Next, as shown in FIG. 6D, for example, the upper surfaces of the element isolation insulating films 7 are etched by an etch-back process using the RIE method. As a result, the upper surfaces of the element isolation insulating films 7 recede from the upper surfaces of the first conductive layers 3 used as floating gate electrodes towards the semiconductor substrate 1 side and the side surfaces of the conductive layers 3 are exposed. Thus, element isolation areas STI and element areas AA defined by the areas STI are formed.

Then, as shown in FIG. 6E, an insulating film 5 used as interelectrode insulating films is formed on the insulating films 4 and element isolation insulating films 7. The insulating film 5 also covers the side surfaces of the conductive layers 3. For example, the insulating film 5 has a laminated structure and, in the following description, the insulating film 5 with the laminated structure used as interelectrode insulating films of the memory cells is referred to as a laminated insulating film 5.

The laminated insulating film 5 has a three-layered structure in an example shown in FIG. 6E. The laminated insulating film 5 has a structure in which a ferroelectric insulating film 51 is sandwiched between two insulating films 50 and 52. A material having a dielectric constant larger than that of the insulating films 50, 52 is used to form the insulating film 51.

The lowermost insulating film 50 of the laminated insulating film 5 is formed on the element isolation insulating films 7, insulating films 4 and side surfaces of the conductive layers 3 by use of the CVD method, for example. As the insulating film 50, for example, a silicon oxide film is used.

The insulating film 51 is formed on the insulating film 50 by use of an ALD (Atomic Layer Deposition) method and CVD method, for example. As the insulating film (High-k film) 51, for example, silicon nitride (SiN), aluminum oxide (Al₂O₃), hafnium oxide (HfO₂), tantalum oxide (Ta₂O₅), lanthanum oxide (La₂O₃), LaLiO₃, zirconium oxide (ZrO₂) or yttrium oxide (Y₂O₃) is used. In this case, silicon or nitrogen may be further added to the above oxide film configuring the insulating film 51.

The uppermost insulating film 52 of the laminated insulating film 5 is formed on the ferroelectric insulating film 51 by use of the CVD method, for example. As the insulating film 52, a silicon oxide film is used, for example.

Next, as shown in FIG. 6G, opening portions Q are formed in selection transistor forming regions by use of, for example, the RIE method to expose the upper surfaces of the conductive layer 3. FIG. 6G shows the cross section in the same direction as FIG. 2. After the opening portions Q are formed, a second conductive layer 6 used as control gate electrodes is formed by use of the CVD method, for example. As the second conductive layer 6, a polysilicon film is used, for example. In the above step, the conductive layer 6 makes contact with the conductive layer 3 via the opening portions Q in the selection transistor forming regions.

FIG. 6F shows the structure obtained after the second conductive layer 6 is formed in the cross section shown in FIG. 6E.

After this, as shown in FIGS. 2 and 3, the memory cells MC and selection transistors STD, STS are processed into a stripe pattern along the channel width direction (gate width direction) by use of the photolithography technique so as to respectively have preset gate sizes (gate lengths). Based on the above pattern, the conductive layer 6, insulating film 5, insulating film 4, conductive layer 3 and insulating film 2 are sequentially etched by use of the RIE method, for example.

Thus, floating gate electrodes 3a and control gate electrodes 6a of the memory cells MC are formed on tunnel insulating films 2a on the surface of the semiconductor substrate 1. Likewise, lower gate electrodes 3b and upper electrodes 6b of the selection transistors STD, STS are formed on gate insulating films 2b on the surface of the semiconductor substrate 1.

In this embodiment, interelectrode insulating films 4a are formed on the floating gate electrodes 3a and the insulating films 4a are disposed between the floating gate electrodes 3a and the control gate electrodes 6a. Further, the interelectrode insulating films 5a with the laminated structure are formed not only on the upper surfaces of the floating gate electrodes 3a but also on the side surfaces thereof. The control gate electrodes 6a cover the side surfaces of the floating gate electrodes 3a with the interelectrode insulating films 5a disposed therebetween.

Gate electrodes 3b, 6b of the selection transistors STD, STS are formed on the gate insulating films 2b on the surface of the semiconductor substrate 1 at the same time as formation of the gate electrodes 3a, 6a of the memory cells MC. In the selection transistors STD, STS, the upper gate electrodes 6b make contact with the lower gate electrodes 3B on the gate insulating films 2b via the opening portions Q.

Then, source/drain diffusion layers 8a, 8d, 8s are formed in the semiconductor substrate 1 in a self-alignment fashion with the gate electrodes 3a, 3b, 6a, 6b used as a mask. As a result, the memory cells MC and selection transistors STD, STS are formed in the memory cell array.

After the source/drain diffusion layers 8a, 8d, 8s are formed, an insulating film that covers the gate electrodes 3a, 3b, 6a, 6b is formed on the semiconductor substrate 1. The insulating film is etched to expose the upper surfaces of the control gate electrodes 6a and upper gate electrodes 6b. Next, for example, a metal layer (nickel (Ni) film) is deposited on the exposed portions of the control gate electrodes 6a and upper gate electrodes 6b. Then, the control gate electrodes 6a and upper gate electrodes 6b are subjected to a silicide process. By the silicide process, metal atoms (for example, Ni atoms) are thermally diffused into the control gate electrodes 6a and upper gate electrodes 6b and the control gate electrodes 6a and upper gate electrodes 6b are converted from the polysilicon layer to a silicide layer. The silicide process may be performed to form the whole portion of the conductive layer 6 into a silicide form so as to form the conductive layer into one silicide layer. Alternatively, the silicide process may be performed to form only the upper portion of the conductive layer 6 into a silicide form so as to provide a polycide structure.

After the silicide process, an insulating film is deposited again to cover the exposed upper surfaces of the control gate electrodes 6a and upper gate electrodes 6b by use of the CVD method so as to form a first inter-level insulating layer 11.

Then, after a flattening process is performed for the inter-level insulating layer 11, source line/bit line contacts SC, BC are buried in the insulating layer 11 and formed in direct contact with the diffusion layers 8d, 8s in contact forming regions. After this, source lines SL and metal interconnections MO are formed on the inter-level insulating layer 11 to be electrically connected to the source line/bit line contacts SC, BC, respectively.

Then, a second inter-level insulating layer 12 is formed on the inter-level insulating layer 11 by use of, for example, the CVD method to cover the source lines SL and metal interconnections MO. Subsequently, after via contacts VC connected to the metal interconnections MO are buried in the inter-level insulating layer 12, bit lines BL are formed on the inter-level insulating layer 12 to be connected to the via contacts VC.

By the above manufacturing process, a flash memory according to the embodiment of this invention is completed.

In this embodiment, the first interelectrode insulating films 4a are formed on the upper portions of the floating gate electrodes 3a and the second interelectrode insulating films 5a are formed on the upper portions and side portions of the floating gate electrodes 3a. Therefore, the memory cell MC has a structure in which the insulating film 4a, 5a are disposed on the upper portion of the floating gate electrode 3a between the floating gate electrode 3a and the control gate electrode 6a and the insulating films 5a is disposed at the side portions thereof. As a result, a memory cell having small coupling capacity formed between the upper portion of the floating gate electrodes 3a and the control gate electrode 6a that faces thereto is formed.

Thus, according to the manufacturing method of this embodiment, concentration of an electric field with respect to the interelectrode insulating films 5a between the floating gate electrodes 3a and the control gate electrodes 6a can be avoided in the upper portions of the floating gate electrodes 3a. Therefore, it is possible to form a memory cell whose leak-resistant property will not be degraded even if the memory cell is miniaturized.

(Modification)

This invention is not limited to the above embodiment. In the above embodiment, the NAND flash memory is explained as an example, but this invention can also be applied to an OR or NOR flash memory. Further, the conditions of the film thickness and material of the interelectrode insulating film can be adequately modified according to the specification.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a plurality of nonvolatile memory cells formed on a semiconductor substrate,
each of the memory cells including:
a tunnel insulating film formed on the semiconductor substrate,
a floating gate electrode formed on the tunnel insulating film,
an interelectrode insulating film formed to cover an upper surface and a part of side surfaces of the floating gate electrode, a film thickness of the interelectrode insulating film being made larger on the upper surface of the floating gate electrode than on the side surface of the floating gate electrode, and
a control gate electrode formed on the interelectrode insulating film.

2. The device according to claim 1, wherein the tunnel insulating film is configured by one of a silicon oxide film, silicon oxynitride film and aluminum oxide film and the interelectrode insulating film is an insulating film having a dielectric constant larger than that of the tunnel insulating film.

3. The device according to claim 1, wherein the interelectrode insulating film comprises a first interelectrode insulating film formed on the upper surface of the floating gate electrode and a second interelectrode insulating film formed to cover the side surfaces of the floating gate electrode and the first interelectrode insulating film.

4. The device according to claim 3, wherein the first interelectrode insulating film is configured by one of a silicon oxide film and silicon nitride film and the second interelectrode insulating film has a three-layered structure configured by sandwiching a first insulating film having a dielectric constant larger than that of the silicon oxide film between two second insulating films having a dielectric constant smaller than that of the first insulating film.

5. The device according to claim 1, wherein a plurality of memory cells are serially connected to configure a NAND cell unit.

6. The device according to claim 1, wherein the interelectrode insulating film is formed to cover the upper surface and a part of the side surfaces of the floating gate electrode along a channel length direction of the floating gate electrode.

7. The device according to claim 1, wherein the control gate electrode, interelectrode insulating film, floating gate electrode and tunnel insulating film are formed to gate structures, grooves are each formed between the gate structures adjacent in a channel direction in the substrate, and element isolation insulating films are buried in the grooves and between the gate structures to a position that is higher than a lowermost surface of the floating gate electrode and lower than an uppermost surface thereof.

8. A manufacturing method of a nonvolatile semiconductor memory device having a plurality of nonvolatile memory cells integrated on a semiconductor substrate, comprising:
forming a floating gate electrode on the semiconductor substrate with a tunnel insulating film disposed therebetween,
forming a first interelectrode insulating film on the floating gate electrode,
processing the first interelectrode insulating film and floating gate electrode into a gate pattern,
forming a second interelectrode insulating film to cover the first interelectrode insulating films and a part of side surfaces of the floating gate electrodes processed into the gate pattern, and
forming a control gate electrode on the second interelectrode insulating film.

9. The method according to claim 8, wherein the first interelectrode insulating film, floating gate electrode and tunnel insulating film are processed into a stripe pattern in a gate length direction to form the gate pattern, exposed surface portions of the substrate are etched to form groove portions and element isolation insulating films are buried in the groove portions and between adjacent gate portions before the second interelectrode insulating film is formed.

10. The method according to claim 9, wherein the element isolation insulating films are etched to a position that is higher than a lowermost surface of the floating gate electrode and lower than an uppermost surface thereof.

11. The method according to claim 8, wherein one of a silicon oxide film, silicon oxynitride film and aluminum oxide film is formed as the tunnel insulating film and an insulating film having a dielectric constant larger than that of the tunnel insulating film is formed as the interelectrode insulating film.

12. The method according to claim 9, wherein one of a silicon oxide film and silicon nitride film is formed as the first interelectrode insulating film and the second interelectrode insulating film is formed with a three-layered structure configured by sandwiching a first insulating film having a dielectric constant larger than that of the silicon oxide film between two second insulating films having a dielectric constant smaller than that of the first insulating film.

13. The method according to claim 8, wherein a plurality of memory cells are serially connected to configure a NAND cell unit.

14. A manufacturing method of a nonvolatile semiconductor memory device having a plurality of nonvolatile memory cells integrated on a semiconductor substrate, comprising:
forming a tunnel insulating film on the substrate,
forming a floating gate electrode on the tunnel insulating film,
forming a first interelectrode insulating film on the floating gate electrode,
processing the first interelectrode insulating film and floating gate electrode into a stripe pattern in a gate length direction,
forming a second interelectrode insulating film to cover the first interelectrode insulating films and a part of side surfaces of the floating gate electrodes processed into the stripe pattern,
forming a control gate electrode on the second interelectrode insulating film, and
processing the control gate electrode, second interelectrode insulating film, first interelectrode insulating film and floating gate electrode into a stripe pattern in a gate width direction.

15. The method according to claim 14, wherein the first interelectrode insulating film, floating gate electrode and tunnel insulating film are processed into a stripe pattern in a gate length direction to formed the stripe pattern, exposed surface portions of the substrate are etched to form groove portions and element isolation insulating films are buried in the groove portions and between adjacent gate portions before the second interelectrode insulating film is formed.

16. The method according to claim 15, wherein the element isolation insulating films are etched to a position that is higher than a lowermost surface of the floating gate electrode and lower than an uppermost surface thereof.

17. The method according to claim 14, wherein one of a silicon oxide film and silicon nitride film is formed as the first interelectrode insulating film and the second interelectrode insulating film is formed with a three-layered structure configured by sandwiching a ferroelectric insulating film having a dielectric constant larger than that of the silicon oxide film between insulating films having a dielectric constant smaller than that of the ferroelectric insulating film.

18. The method according to claim 14, wherein a plurality of memory cells are serially connected to configure a NAND cell unit.
